(19) United States
(12) Patent Application Publication
(10) Pub. No.: US 2016/0340800 A1
(43) Pub. Date: Nov. 24, 2016

(54) VAPOR PHASE GROWTH APPARATUS AND VAPOR PHASE GROWTH METHOD

(71) Applicant: NuFlare Technology, Inc., Kanagawa (JP)

(72) Inventors: Hideki ITO, Yokohama-shi (JP); Yuusuke SATO, Tokyo (JP)

(21) Appl. No.: 15/156,888

(22) Filed: May 17, 2016

(30) Foreign Application Priority Data
May 19, 2015 (JP) 2015-101635

(51) Int. Cl. C30B 25/16; C30B 25/10

(52) U.S. Cl. CPC C30B 25/16; C30B 25/10

(57) ABSTRACT

A vapor phase growth apparatus includes: a first supporter supporting a first substrate; a first heater heating the first substrate; a first gas feeder supplying a first process gas onto a surface of the first substrate; a first radiation thermometer measuring a first temperature on the surface of the first substrate, the first temperature taking no account of an effect of emissivity of the first substrate; a first thermometer acquiring an actual temperature of the first substrate; a first temperature controller controlling the actual temperature to be a predetermined temperature by using the first heater; a second supporter supporting a second substrate; a second heater heating the second substrate; a second radiation thermometer measuring a second temperature on a surface of the second substrate, the second temperature taking no account of an effect of emissivity of the second substrate; and a second temperature controller controlling the second heater based on the first temperature, the actual temperature, and the second temperature.

### CROSS-REFERENCE TO RELATED APPLICATION

This application is based upon and claims the benefit of priority from Japanese Patent Applications No. 2015-101635, filed on May 19, 2015, the entire contents of which are incorporated herein by reference.

### FIELD OF THE INVENTION

Embodiments described herein relate generally to a vapor phase growth method and a vapor phase growth apparatus.

### BACKGROUND OF THE INVENTION

An example of methods for depositing a high-quality semiconductor film is an epitaxial growth technique for growing a single crystal film on a wafer (substrate) by vapor phase growth. In a vapor phase growth method and a vapor phase growth apparatus using the epitaxial growth technique, the wafer is supported by a supporter in a reactor maintained under atmospheric pressure or low pressure, and is heated. Next, a reactant gas to be a material for film deposition is supplied onto the wafer. A thermal reaction of the reactant gas or the like occurs on a surface of the wafer. An epitaxial single crystal film is deposited on the surface of the wafer.

Temperature of the substrate during the film deposition can be measured by using a radiation thermometer. The radiation thermometer is a thermometer that measures and converts thermal radiation intensity from a surface of an object into temperature so that the temperature of the object is measured. An advantage of the radiation thermometer is that measurement can be performed in a short time without being in contact with the substrate. However, emissivity, that is a ratio W′/W of radiant exitance W′ of the thermal radiation of the object to radiant exitance W of thermal radiation of a black body, depends on a surface condition and temperature upon the film deposition in addition to the material to be deposited, as a film, on the substrate. Thus, the temperature of the substrate cannot be accurately measured. For example, correction is performed using emissivity that has measured by using a predetermined light source simultaneously. Thus, more accurate temperature can be acquired.

### SUMMARY OF THE INVENTION

A vapor phase growth apparatus according to an embodiment includes: a first supporter supporting a first substrate; a first heater heating the first substrate; a first gas feeder supplying a first process gas onto a surface of the first substrate; a first radiation thermometer measuring a first temperature on the surface of the first substrate, the first temperature taking no account of an effect of emissivity of the first substrate; a first thermometer acquiring an actual temperature of the first substrate; a first temperature controller controlling the actual temperature to be a predetermined temperature by using the first heater; a second supporter supporting a second substrate; a second heater heating the second substrate; a second radiation thermometer measuring a second temperature on a surface of the second substrate, the second temperature taking no account of an effect of emissivity of the second substrate; and a second temperature controller controlling the second heater based on the first temperature, the actual temperature, and the second temperature.

A vapor phase growth method according to an embodiment includes: heating a first substrate; measuring a first temperature on a surface of the first substrate, the first temperature taking no account of an effect of emissivity of the first substrate; acquiring an actual temperature of the first substrate; controlling the actual temperature to be a predetermined temperature; measuring a second temperature on a surface of a second substrate, the second temperature taking no account of an effect of emissivity of the second substrate; and heating the second substrate based on the first temperature, the actual temperature, and the second temperature.

### BRIEF DESCRIPTION OF THE DRAWINGS

FIG. 1 is a schematic view of a vapor phase growth apparatus according to a first embodiment;

FIG. 2 is a block diagram of a part of the vapor phase growth apparatus according to the first embodiment;

FIG. 3 is a flow chart of a vapor phase growth method according to the first embodiment;

FIG. 4 is a schematic view of a vapor phase growth apparatus according to a second embodiment;

FIG. 5 is a block diagram of a part of the vapor phase growth apparatus according to the second embodiment; and

FIG. 6 is a flow chart of a vapor phase growth method according to the second embodiment.

### DETAILED DESCRIPTION OF THE EMBODIMENTS

Embodiments of the present disclosure will be described with reference to the drawings.

Note that, in the following descriptions, a substrate includes a thin film deposited or formed on the substrate.

### First Embodiment

A vapor phase growth apparatus according to the present embodiment includes: a first supporter supporting a first substrate; a first heater heating the first substrate; a first gas feeder supplying a first process gas onto a surface of the first substrate; a first radiation thermometer measuring a first temperature on the surface of the first substrate, the first temperature taking no account of an effect of emissivity of the first substrate; a first thermometer acquiring an actual temperature of the first substrate; a first temperature controller controlling the actual temperature to be a predetermined temperature by using the first heater; a second supporter supporting a second substrate; a second heater heating the second substrate; a second radiation thermometer measuring a second temperature on a surface of the second substrate, the second temperature taking no account of an effect of emissivity of the second substrate; and a second temperature controller controlling the second heater based on the first temperature, the actual temperature, and the second temperature.

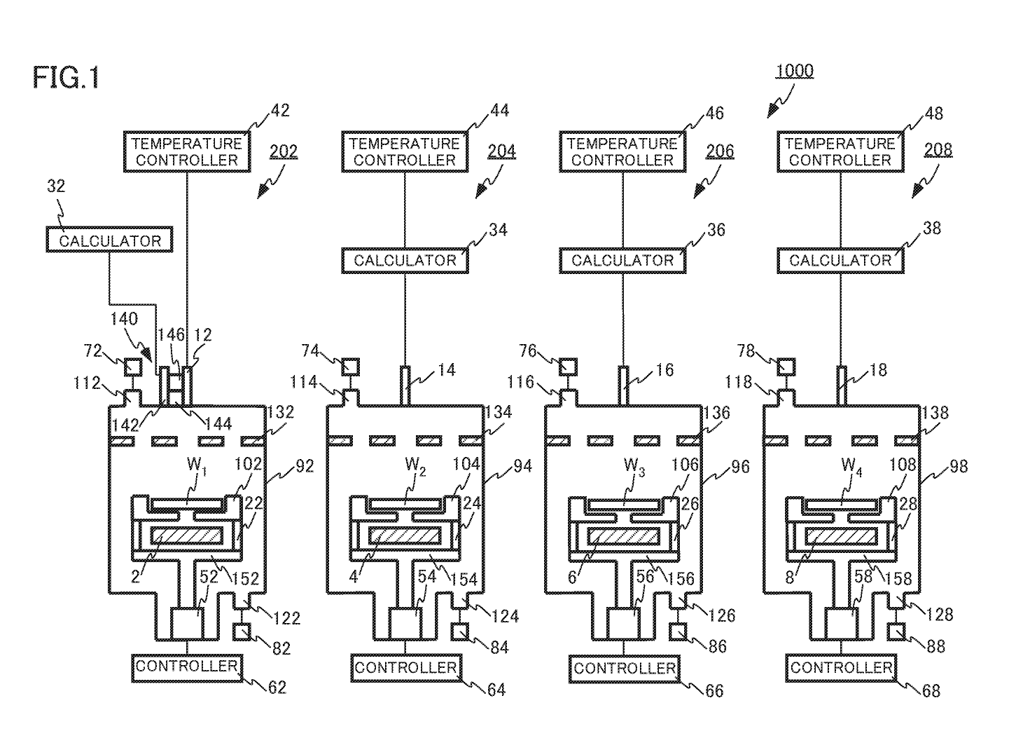

FIG. 1 is a schematic cross-sectional view of the vapor phase growth apparatus according to the present embodiment. The vapor phase growth apparatus according to the present embodiment is, for example, a vertical and single wafer type epitaxial growth apparatus using a metal organic chemical vapor deposition method (MOCVD method). The epitaxial growth apparatus according to the present embodiment grows a single crystal film of a nitride-based semiconductor, such as gallium nitride (GaN), aluminum nitride (AlN), gallium aluminum nitride (AlGaN), indium gallium nitride (InGaN), or silicon nitride (SiN).

The vapor phase growth apparatus 1000 includes a vapor phase growth unit 202 as a reference of temperature control, and vapor phase growth units 204, 206, and 208. Note that, the number of vapor phase growth units is four in the descriptions according to the present embodiment. However, the number of vapor phase growth units and the like is not particularly limited if being two or more.

The vapor phase growth units 202, 204, 206, and 208 include reaction vessels 92, 94, 96, and 98 in which film deposition processing is performed on substrates W₁, W₂, W₃, and W₄, respectively. The reaction vessels 92, 94, 96, and 98 are preferably identical to each other in shape and size in order to cause thicknesses and properties of films to be deposited on the substrates W₁, W₂, W₃, and W₄ including, for example, silicon (Si), sapphire, silicon carbide (SiC), or gallium nitride (GaN), to be substantially the same, respectively.

Supporters 102, 104, 106, and 108 are provided in the reaction vessels 92, 94, 96, and 98, respectively. A holder having an opening at the center and supporting a substrate by a circumferential edge, is used for each of the supporters 102, 104, 106, and 108. A susceptor including no opening may be used instead. The supporters 102, 104, 106, and 108 are disposed on rotating rings 22, 24, 26, and 28, respectively. The rotating rings 22, 24, 26, and 28 are, for example, coupled to rotating mechanisms 52, 54, 56, and 58 through rotating bases 152, 154, 156, and 158, respectively.

The reaction vessels 92, 94, 96, and 98 each include a substrate unloading/loading port not illustrated. The substrate unloading/loading port is used for loading of a substrate to the inside of each of the reaction vessels and for unloading of the substrate to the outside of each of the reaction vessels. Here, for example, a robot hand not illustrated is used for the unloading/loading of the substrate. The substrate that has been loaded by the robot hand is supported by the supporter in the reaction vessel. Note that the method of unloading/loading the substrate is not limited to this.

Gas feeders 72, 74, 76, and 78 are provided in order to supply a process gas into the reaction vessels 92, 94, 96, and 98, respectively. Examples of the process gas include trimethyl gallium (TMG), trimethyl indium (TMI), trimethyl aluminum (TMA), ammonia (NH₃) gas, nitrogen (N₂) gas, and hydrogen (H₂) gas. Here, the gas feeders each include, for example, a gas cylinder, a laying pipe, a valve, a flow controller, such as a mass flow controller, not illustrated.

The reaction vessels 92, 94, 96, and 98 include gas inlets 112, 114, 116, and 118, and outlets 122, 124, 126, and 128, respectively. The process gas is supplied from the gas inlets 112, 114, 116, and 118 to the insides of the reaction vessels 92, 94, 96, and 98, respectively. After passing through shower plates 132, 134, 136, and 138 provided in the reaction vessels 92, 94, 96, and 98, the process gas that has been supplied is supplied onto the substrates W₁, W₂, W₃, and W₄ so as to be used for growing of a film, namely, film deposition, respectively. A surplus of the process gas and a reaction by-product caused by the film deposition are exhausted from ejectors 82, 84, 86, and 88 through the outlets 122, 124, 126, and 128, respectively. Here, the ejectors 82, 84, 86, and 88 are, for example, an exhausting system including a pressure control valve and a vacuum pump that have been already known.

Here, the shower plates 132, 134, 136, and 138 each preferably have identical shape. This is because if the shower plates 132, 134, 136, and 138 each have identical shape, since a supplying state of a reactant gas to each of the substrates W₁, W₂, W₃, and W₄ becomes constant in the reaction vessels 92, 94, 96, and 98, a state of an air flow of the reactant gas on each of the substrates W₁, W₂, W₃, and W₄ can be identical to each other, and a quality of the film to be deposited can be uniform.

The ejectors 82, 84, 86, and 88 preferably have identical exhausting speed. This is because to make an exhausting state of the reactant gas identical each other and to make the quality of the film to be deposited on each of the substrates W₁, W₂, W₃, and W₄ identical each other.

Heaters 2, 4, 6, and 8 that include a heater or the like and heat the substrates W₁, W₂, W₃, and W₄ from back surfaces, are provided inside of the rotating rings 22, 24, 26, and 28, respectively. The heaters 2, 4, 6, and 8 are supplied with electric power by an external power source not illustrated so as to generate heat.

For example, a circuit board can be used for each of controllers 62, 64, 66, and 68, calculators 32, 34, 36, and 38, temperature controllers 42, 44, 46, and 48, and an actual temperature calculator 146. Each of the controllers, calculators, temperature controllers and actual temperature calculator is not limited to the circuit board. For example, a microprocessor mainly including a central processing unit (CPU), a read only memory (ROM) for storing a processing program, a random access memory (RAM) for temporarily storing data, an input/output port, and a communication port may be used. Otherwise, controllers 62, 64, 66, and 68, calculators 32, 34, 36, and 38, temperature controllers 42, 44, 46, and 48, and an actual temperature calculator 146 include a one processing circuitry. The processing circuitry includes, e.g. an electronic circuit, a computer, a processor, a circuit board, a quantum circuit, or a semiconductor device. A common processing circuitry may be used for each of the controllers, calculators, temperature controllers and actual temperature calculator. Each different processing circuitry may be used for each of the controllers, calculators, temperature controllers and actual temperature calculator.

The controller 62 which controls the vapor phase growth unit 202 as the reference of temperature control, is coupled to the temperature controller 42, the rotating mechanism 52, the gas feeder 72, and the ejector 82 through wirings not illustrated. The controller 62 controls a rotation and a rotating speed of the substrate W₁ through the rotating ring 22 by the rotating mechanism 52, control supplying a material, such as the reactant gas, to the reaction vessel 92 by the gas feeder 72, control transferring the first substrate W₁ by the robot hand, control exhausting the reactant gas and a product by the ejector 82, and control opening/closing the substrate unloading/loading port not illustrated in the reaction vessel 92, and the like.

The controllers 64, 66, and 68, which control the vapor phase growth unit 204, 206, and 208 to be controlled in temperature on the basis of the vapor phase growth unit 202, are coupled to the temperature controllers 44, 46, and 48, the rotating mechanisms 54, 56, and 58, the gas feeders 74, 76, and 78, and the ejectors 84, 86, and 88 through wiring not illustrated, respectively. The controllers 64, 66, and 68 control rotations and rotating speeds of the substrates W₂, W₃, and W₄ through the rotating rings 24, 26, and 28 by the rotating mechanisms 54, 56, and 58, control supplying a material, such as the reactant gas, to the reaction vessels 94, 96, and 98 by the gas feeders 74, 76, and 78, control transferring the substrates W₂, W₃, and W₄ by the robot hand, control exhausting the reactant gas and a product by the ejectors 84, 86, and 88, and control opening/closing the substrate unloading/loading port not illustrated in the reaction vessels 94, 96, and 98, and the like, respectively.

Note that, the rotating mechanisms 52, 54, 56, and 58 each include, for example, a motor or a combination of the motor and a gear.

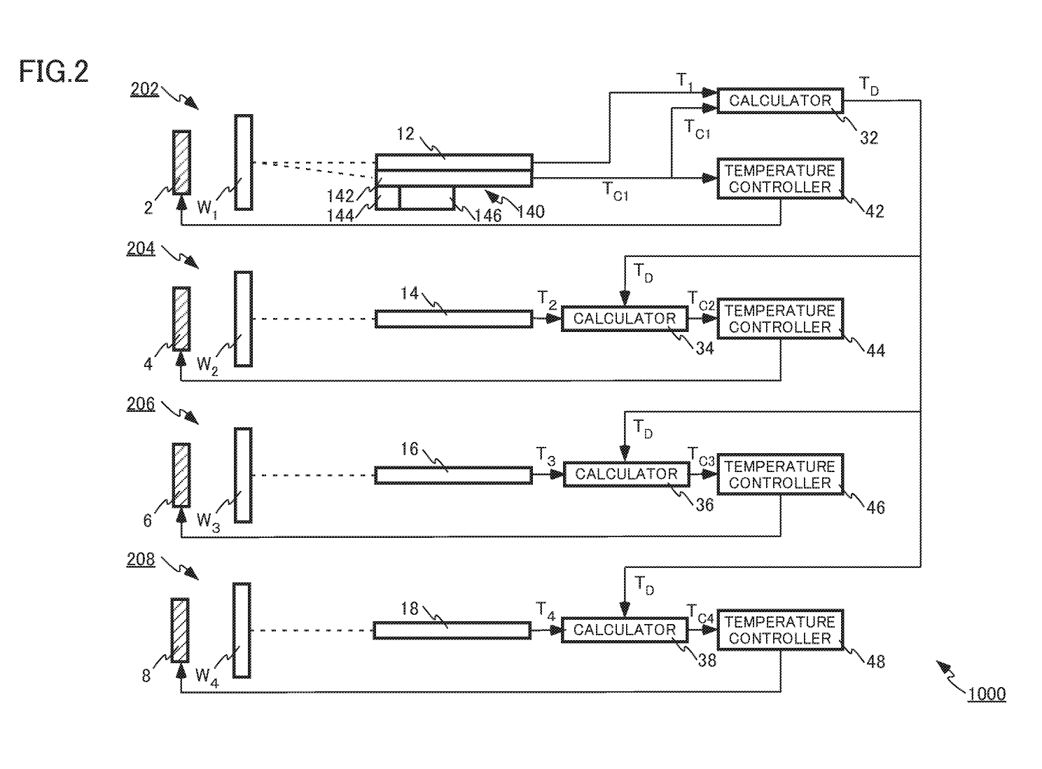

FIG. 2 is a block diagram of a part of the vapor phase growth apparatus according to the present embodiment.

In the vapor phase growth unit 202 as the reference of temperature control, a radiation thermometer 12 measures a temperature T₁ (first temperature) taking no account of an effect of emissivity of the first substrate W₁, on a surface of the first substrate W₁. The temperature T₁ that have been measured is input into the calculator 32.

For example, an emissivity correction pyrometer (ECP) is used as a thermometer 140 for measuring an actual temperature T_{C1} of the substrate W₁. In the ECP, the actual temperature T_{C1} to which emissivity correction has been performed, is measured by a radiation thermometer 142, an emissivity measure 144, and the actual temperature calculator 146. As described above, the actual temperature T_{C1}acquired by the thermometer 140 is input into the calculator 32 and the temperature controller 42.

Note that, without using the ECP, the temperature T₁ taking no account of the effect of emissivity of the first substrate W₁, measured by the radiation thermometer 12, may be corrected by the first calculator 32 based on the emissivity separately measured and the actual temperature T_{C1} of the substrate W₁ may be acquired.

The calculator 32 uses the temperature T₁ and the actual temperature T_{C1} and calculates a difference-temperature T_{D} that is a difference between the temperature T₁ and the actual temperature T_{C1}. The difference-temperature T_{D} is calculated, for example, by an expression of T_{D}=T_{C1}−T₁. The difference-temperature T_{D} is input into the calculators 34, 36, and 38 in the vapor phase growth units 204, 206, and 208, respectively.

The radiation thermometers 14, 16, and 18 measure temperatures T₂, T₃, and T₄ taking no account of an effect of emissivity, on surfaces of the substrates W₂, W₃, and W₄, respectively. The T₂, T₃, and T₄ that have been measured are input into the calculators 34, 36, and 38, respectively.

With respect to the substrates W₂, W₃, and W₄, the temperatures T₂, T₃, and T₄ measured by the radiation thermometers 14, 16, and 18, respectively, are corrected based on the temperature T₁ and the actual temperature T_{C1} of the substrate W₁. In order to perform correction conversion to the temperatures T₂, T₃, and T₄, for example, the temperatures T₂, T₃, and T₄ are added with the difference-temperature T_{D} so as to be correction temperatures T_{C2}, T_{C3}, and T_{C4}, respectively. The calculator 34 uses the second temperature T₂ and the difference-temperature T_{D} and calculates the correction temperature T_{C2} of the substrate W₂. For example, the calculation is performed by adding the difference-temperature T_{D} to the temperature T₂ by an expression of T_{C2}=T₂+T_{D}. Similarly, the calculator 36 uses the temperature T₃ and the difference-temperature T_{D} and acquires the correction temperature T_{C3} of the substrate W₃, for example, by an expression of T_{C3}=T₃+T_{D}. The calculator 38 uses the temperature T₄ and the difference-temperature T_{D} and acquires the correction temperature T_{C4} of the substrate W₄, for example, by an expression of T_{C4}=T₄+T_{D}.

The temperature controller 42 is coupled to the thermometer 140 and the heater 2. The temperature controller 42 uses the heater 2 in order that the actual temperature T_{C1} should be controlled to be a predetermined temperature. The temperature controllers 44, 46, and 48 are coupled to the radiation thermometers 14, 16, and 18, the calculators 34, 36, and 38, and the heaters 4, 6, and 8, respectively. The temperature controllers 44, 46, and 48 use the heaters 4, 6, and 8 in order that the correction temperatures T_{C2}, T_{C3}, and T_{C4} should be predetermined temperatures, respectively.

Here, the temperature controller, for example, controls electric power to be applied to the heater so as to control the temperature of the substrate. Note that, the above pieces of control performed by the temperature controllers 42, 44, 46, and 48, maybe performed by the controllers 62, 64, 66, and 68, respectively. The radiation thermometer and the temperature controller may be directly coupled to each other through a signal communication unit, such as wiring, or may be indirectly coupled to each other through the calculator or the like.

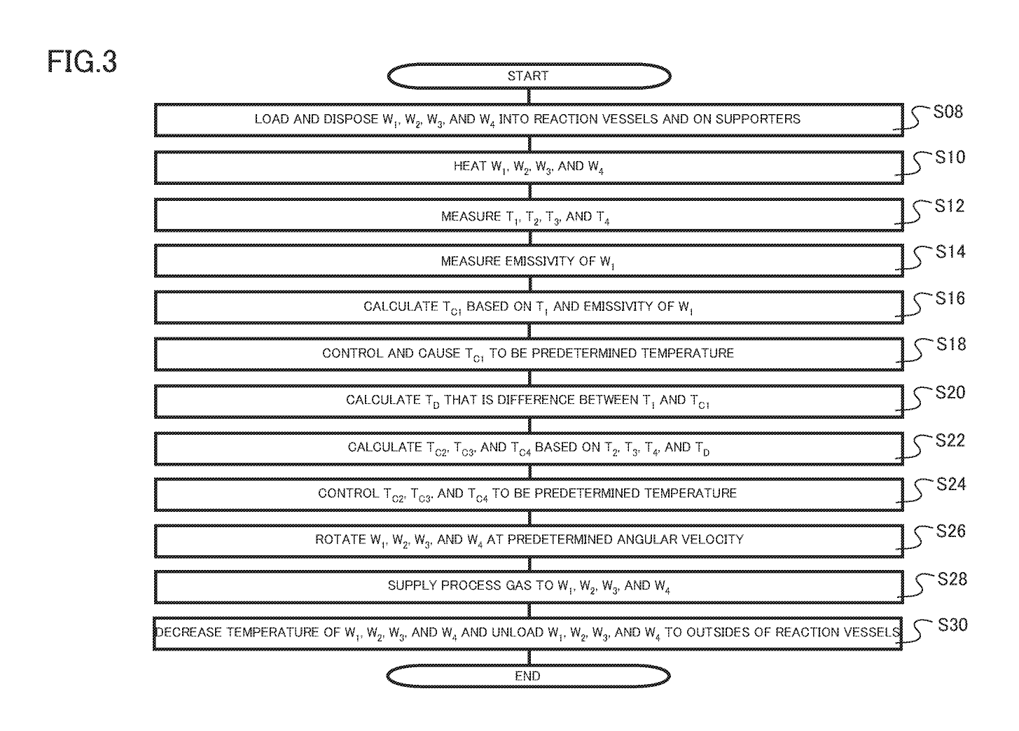

FIG. 3 is a flow chart of the vapor phase growth method according to the present embodiment.

First, the controllers 62, 64, 66, and 68 load the substrates W₁, W₂, W₃, and W₄ into the reaction vessels 92, 94, 96, and 98, for example, by using the robot hand, so as to dispose the substrates W₁, W₂, W₃, and W₄ on the supporters 102, 104, 106, and 108, respectively (S08).

Next, the controllers 62, 64, 66, and 68 use the heaters 2, 4, 6, and 8 so as to heat the substrates W₁, W₂, W₃, and W₄, respectively (S10).

Next, the temperature controller 42 uses the radiation thermometer 12 so as to measure the temperature T₁ taking no account of the effect of emissivity of the substrate W₁, on the surface of the substrate W₁. The temperature controllers 44, 46, and 48 use the radiation thermometers 14, 16, and 18 so as to measure the temperatures T₂, T₃, and T₄ taking no account of the effect of emissivity, on the surfaces of the substrates W₂, W₃, and W₄, respectively. Note that, here, the temperature T₁ of the substrate W₁ maybe measured by the radiation thermometer 142 (S12).

Next, the thermometer 140 uses the radiation thermometer 142 so as to measure the temperature T₁ taking no account of the effect of emissivity, on the surface of the substrate W₁. Note that, here, the temperature T₁ may be measured by the radiation thermometer 12. Next, the thermometer 140 uses the emissivity measure 144 so as to measure the emissivity of the substrate W₁ (S14). Next, the thermometer 140 uses the actual temperature calculator 146 and calculates the actual temperature T_{C1} based on the temperature T₁ and the emissivity of the substrate W₁ (S16). Next, the temperature controller 42 uses the heater 2 so that the actual temperature T_{C1} is controlled so as to be the predetermined temperature (S18). Next, the calculator 32 uses the temperature T₁ and the actual temperature T_{C1}, and calculates the difference-temperature T_{D}, for example, by the expression of T_{D}=T_{C1}−T₁ (S20). The emissivity measure 144, includes, e.g., a photodetector and a calculating circuit or a calculator which calculates an emissivity. The emissivity measure 144 measures the thermal radiation of the object by using, e.g., the photodetector.

Next, the calculators 34, 36, and 38, for example, add the difference-temperature T_{D} to the temperatures T₂, T₃, and T₄ so as to calculate the correction temperatures T_{C2}, T_{C3}, and T_{C4}, respectively (S22). Note that, the conversion to the correction temperature is not limited to adding the difference-temperature T_{D}. A predetermined function can be used.

Next, the temperature controllers 44, 46, and 48 use the heaters 4, 6, and 8 in order that the correction temperatures T_{C2}, T_{C3}, and T_{C4} should be controlled to the predetermined temperatures, respectively (S24).

Next, the controllers 62, 64, 66, and 68 use the rotating mechanisms 52, 54, 56, and 58, and rotate the substrates W₁, W₂, W₃, and W₄ in an individual circumferential direction at a predetermined rotating speed, respectively (S26). Here, the rotating speed of each of the substrates is preferably equivalent to each other in order to make the quality of the film to be grown on each of the substrates identical to each other.

Next, the controllers 62, 64, 66, and 68 use the gas feeders 72, 74, 76, and 78, and supply the predetermined process gas at a predetermined flow from the gas inlets 112, 114, 116, and 118 onto the surfaces of the substrates W₁, W₂, W₃, and W₄, respectively (S28). Here, examples of the predetermined process gas include reactant gases of trimethyl gallium (TMG), trimethyl indium (TMI), trimethyl aluminum (TMA), ammonia (NH₃) gas, nitrogen (N₂) gas, and hydrogen (H₂) gas. The predetermined process gas is supplied at the predetermined flow so that a predetermined film is deposited on each of the substrates W₁, W₂, W₃, and W₄. Here, kinds of the process gas and flow rates supplied to each of the substrates are preferably identical and equivalent to each other, in order to make the quality of the film to be grown on each of the substrates identical to each other.

After the film deposition has been completed, the temperatures of the substrates Wᵢ, W₂, W₃, and W₄ are decreased and the substrates W₁, W₂, W₃, and W₄ are unloaded to the outside of the reaction vessels 92, 94, 96, and 98, respectively, for example, by using a robot arm (S30).

Note that, according to the present embodiment, vapor phase growth is performed on the substrates as follows: The temperature controller 42 uses the heater 2 in order that the actual temperature T_{C1} should be controlled to be 1100° C. Next, the temperature controllers 44, 46, and 48 use the heaters 4, 6, and 8 in order that the correction temperatures T_{C2}, T_{C3}, and T_{C4} acquired based on the temperature T₁ and the actual temperature T_{C1}, are controlled to be 1100° C., respectively.

Next, an operational effect according to the present embodiment will be described.

In the vapor phase growth apparatus according to the present embodiment, based on an actual temperature measured by providing an emissivity measure in one reaction vessel and performing emissivity correction, and a temperature to which no emissivity correction has performed, measured by a radiation thermometer, temperatures measured by radiation thermometers in other reaction vessels are corrected. Then, temperatures of substrates in the other reaction vessels are controlled with the corrected temperatures. Accordingly, a temperature measuring mechanism can be made to be simple, and temperature control in the other reaction vessels can be performed with high accuracy.

As described above, according to the vapor phase growth method and the vapor phase growth apparatus, the temperature control of the substrates during the film deposition in a plurality of reactors can be easily performed.

### Second Embodiment

A vapor phase growth apparatus according to the present embodiment is different from the vapor phase growth apparatus according to the first embodiment in that the temperatures measured by radiation thermometers in other vapor phase growth units should be controlled to the temperature measured in the vapor phase growth unit as a reference of temperature control without taking account of emissivity, if the actual temperature of the substrate in the vapor phase growth unit as a reference of temperature control is controlled to the predetermined temperature. The descriptions that duplicate with respect to the first embodiment, will be omitted below.

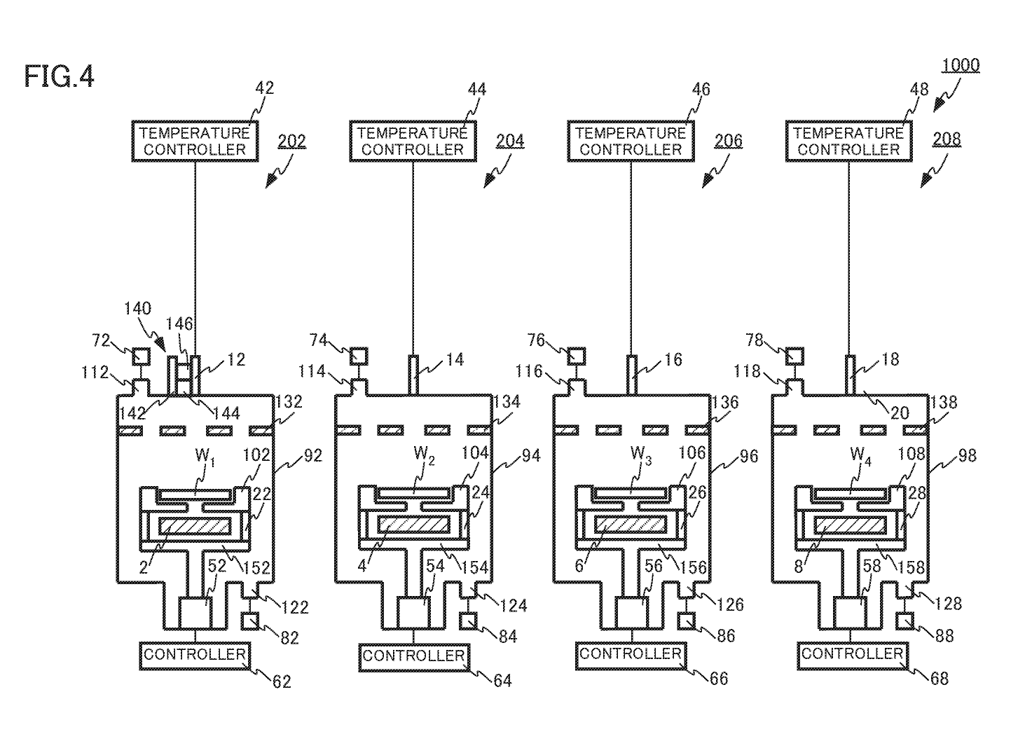

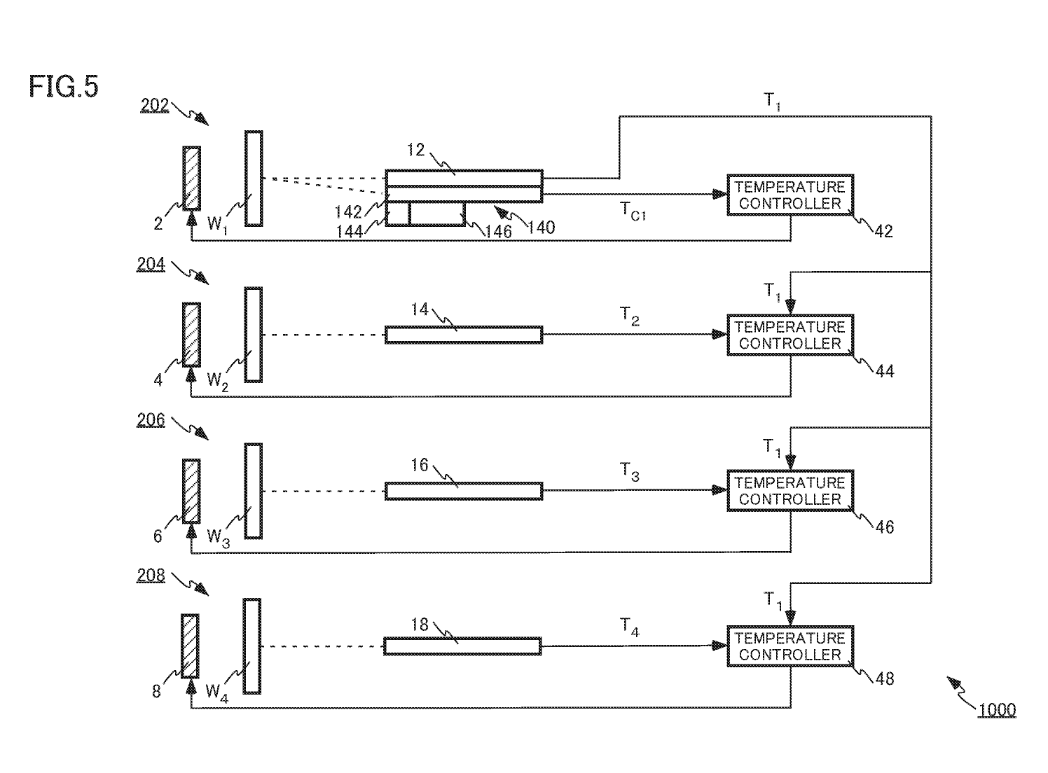

FIG. 4 is a schematic view of the vapor phase growth apparatus according to the present embodiment. FIG. 5 is a block diagram of a part of the vapor phase growth apparatus according to the present embodiment.

Calculators 32, 34, 36, and 38 are not provided in the vapor phase growth apparatus according to the present embodiment. A temperature T₁ measured by a radiation thermometer 12 if an actual temperature T_{C1} of a substrate W₁ is controlled to be a predetermined temperature by a temperature controller 42, is input into temperature controllers 44, 46, and 48. The temperature controllers 44, 46, and 48 use heaters 4, 6, and 8 in order that temperatures T₂, T₃, and T₄ should be controlled to be the temperature T₁, respectively.

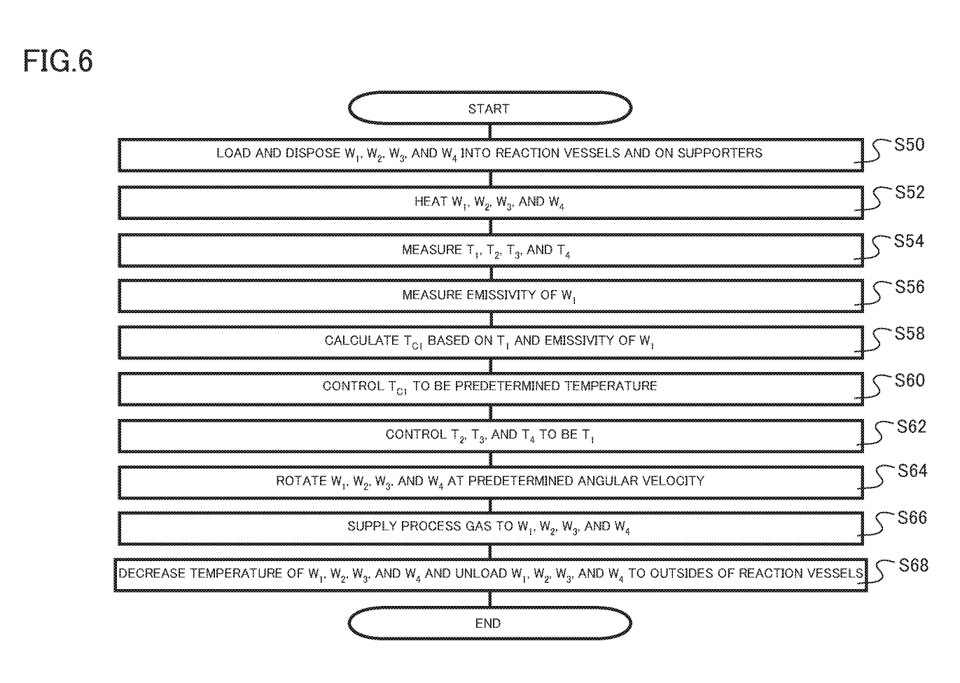

FIG. 6 is a flow chart of a vapor phase growth method according to the present embodiment.

First, controllers 62, 64, 66, and 68 load, for example, using a robot hand, substrates W₁, W₂, W₃, and W₄ into reaction vessels 92, 94, 96, and 98 and the substrates W₁, W₂, W₃, and W₄ are disposed on supporters 102, 104, 106, and 108, respectively (S50).

Next, the controllers 62, 64, 66, and 68 use the heaters 2, 4, 6, and 8 so as to heat the substrates W₁, W₂, W₃, and W₄, respectively (S52).

Next, a temperature controller 42 uses a radiation thermometer 12 so as to measure the temperature T₁ (first temperature) taking no account of emissivity, on a surface of the substrate W₁. Note that, here, the temperature T₁ may be measured by a radiation thermometer 142 (S54).

Next, a thermometer 140 uses an emissivity measure 144 so as to measure the emissivity of the substrate W₁ (S56). Next, the thermometer 140 uses an actual temperature calculator 146 and calculates an actual temperature T_{C1} based on the temperature T₁ and the emissivity of the substrate W₁ (S58).

Next, the temperature controller 42 uses the heater 2 in order that the actual temperature T_{C1} should be controlled to be a predetermined temperature (S60).

Next, the temperature controllers 44, 46, and 48 use the heaters 4, 6, and 8 in order that the temperatures T₂, T₃, and T₄ should be controlled to be the temperature T₁ (S62).

Next, the controllers 62, 64, 66, and 68 use rotating mechanisms 52, 54, 56, and 58 so as to rotate the substrates W₁, W₂, W₃, and W₄ in an individual circumferential direction at a predetermined rotating speed, respectively (S64).

Next, the controllers 62, 64, 66, and 68 use gas feeders 72, 74, 76, and 78, and supply a predetermined process gas at a predetermined flow from gas inlets 112, 114, 116, and 118 onto surfaces of the substrates W₁, W₂, W₃, and W₄, respectively (S66).

Supplying the predetermined process gas at the predetermined flow deposits a desired film on each of the substrates W₁, W₂, W₃, and W₄.

After the film deposition has been completed, the temperature of the substrates W₁, W₂, W₃, and W₄ are decreased in temperature and then are unloaded from the reaction vessels 92, 94, 96, and 98, for example, by using a robot arm (S68).

According to the present embodiment, in a manner similar to the first embodiment, temperature control of a substrate during film deposition in each of a plurality of reactors, can be also easily performed.

According to the embodiments, the thermometers that measure the actual temperature are not limited to the ECP. The place to be measured may be a back surface of a substrate instead of a surface of the substrate. For example, the measurement can be performed by a thermocouple.

As described above, the embodiments of the present disclosure have been described with reference to the specific examples. The above embodiments are exemplary. The present disclosure is not limited to the embodiments. The constituent elements in each of the embodiments can be appropriately combined.

According to the embodiments, parts, such as apparatus configurations and manufacturing methods, that are not directly necessary for describing the present disclosure, have been omitted. For example, a necessary apparatus configuration and manufacturing method can be appropriately selected and used. In addition, all vapor phase growth apparatuses and vapor phase growth methods that include an element according to the present disclosure and can be appropriately designed and changed by a person skilled in the art, are included in the scope of the present disclosure. The scope of the present disclosure is defined by the scope of the claims and the scope of equivalents of the claims.

What is claimed is:

1. A vapor phase growth apparatus comprising:
a first supporter supporting a first substrate;
a first heater heating the first substrate;
a first gas feeder supplying a first process gas onto a surface of the first substrate;
a first radiation thermometer measuring a first temperature on the surface of the first substrate, the first temperature taking no account of an effect of emissivity of the first substrate;
a first thermometer acquiring an actual temperature of the first substrate;
a first temperature controller controlling the actual temperature to be a predetermined temperature by using the first heater;
a second supporter supporting a second substrate;
a second heater heating the second substrate;
a second radiation thermometer measuring a second temperature on a surface of the second substrate, the second temperature taking no account of an effect of emissivity of the second substrate; and
a second temperature controller controlling the second heater based on the first temperature, the actual temperature, and the second temperature.

2. The vapor phase growth apparatus according to claim 1,
wherein the second temperature controller controls the second heater in order that a correction temperature should be controlled to the predetermined temperature, the second temperature being corrected to the correction temperature based on the actual temperature and the first temperature.

3. The vapor phase growth apparatus according to claim 2, further comprising:
a first calculator calculating a difference between the first temperature and the actual temperature; and
a second calculator calculating the correction temperature, the correction temperature being the sum of the difference and the second temperature.

4. The vapor phase growth apparatus according to claim 1,
wherein the second temperature controller controls the second heater in order that the second temperature should be controlled to the first temperature.

5. The vapor phase growth apparatus according to claim 1,
wherein the actual temperature is acquired based on the emissivity of the first substrate and the first temperature.

6. The vapor phase growth apparatus according to claim 5,
wherein the first thermometer includes:
an emissivity measure measuring the emissivity of the first substrate; and
an actual temperature calculator calculating the actual temperature based on the first temperature and the emissivity of the first substrate.

7. The vapor phase growth apparatus according to claim 1, further comprising a second gas feeder supplying a second process gas onto the surface of the second substrate, a kind of the second process gas being identical to a kind of the first gas, a flow rate of the second process gas being identical to a flow rate of the first process gas.

8. The vapor phase growth apparatus according to claim 1, further comprising:
a first reaction vessel including the first substrate and the first supporter provided in the first reaction vessel; and
a second reaction vessel including the second substrate and the second supporter provided in the second reaction vessel, the second reaction vessel having a shape identical to a shape of the first reaction vessel.

9. The vapor phase growth apparatus according to claim 8, further comprising:
a first shower plate provided in the first reaction vessel and supplying the first process gas onto the surface of the first substrate; and
a second shower plate provided in the second reaction vessel and supplying the second process gas onto the surface of the second substrate, the second shower plate having a shape identical to a shape of the first shower plate.

10. The vapor phase growth apparatus according to claim 9, further comprising:
a first ejector exhausting a surplus of the first process gas; and
a second ejector exhausting a surplus of the second process gas, the second ejector having an exhausting speed identical to an exhausting speed of the first ejector.

11. A vapor phase growth method comprising:
heating a first substrate;
measuring a first temperature on a surface of the first substrate, the first temperature taking no account of an effect of emissivity of the first substrate;
acquiring an actual temperature of the first substrate;
controlling the actual temperature to be a predetermined temperature;
measuring a second temperature on a surface of a second substrate, the second temperature taking no account of an effect of emissivity of the second substrate; and
heating the second substrate based on the first temperature, the actual temperature, and the second temperature.

12. The vapor phase growth method according to claim 11, further comprising heating the second substrate in order that a correction temperature should be controlled to the predetermined temperature, the second temperature being corrected to the correction temperature based on the actual temperature and the first temperature.

13. The vapor phase growth method according to claim 11, further comprising heating the second substrate in order that the second temperature should be controlled to the first temperature.

14. The vapor phase growth method according to claim 11, further comprising:
supplying a first process gas onto the surface of the first substrate; and
supplying a second process onto the surface of the second substrate, a kind of the second process gas being identical to a kind of the first gas, a flow rate of the second process gas being identical to a flow rate of the first process gas.
